(19) United States
(12) Patent Application Publication
(10) Pub. No.: US 2009/0167373 A1
(43) Pub. Date: Jul. 2, 2009

(54) MULTI-PHASE FREQUENCY DIVIDER

(75) Inventor: Wenyi Song, San Jose, CA (US)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/994,245

(22) PCT Filed: Jun. 30, 2006
(86) PCT No.: PCT/IB06/52217

§ 371 Date: Oct. 24, 2008

Related U.S. Application Data
(60) Provisional application No. 60/696,489, filed on Jun. 30, 2005.

(51) Int. Cl. H03K 21/00; H03K 3/00

(52) U.S. Cl. 327/115; 327/258

(57) ABSTRACT

A multi-phase frequency divider comprises dynamic inverters connected in a ring and the intermediate nodes around the ring are stabilized with cross-coupled latches. Clock input pulses enable each dynamic inverter's output and will force a corresponding change-of-state in the cross-coupled latches. The multi-phase output is presented in parallel on all the latches.

The present invention relates to electronic digital circuitry, and more particularly to multi-phase frequency dividers.

In the past, single-frequency, single-phase digital clocks were used in computers and a variety of electronic devices. Generating or synthesizing such clocks directly or with phase locked loops (PLL's) and dividers has been straightforward and the technical art is highly developed.

New types of processors and power converters are making novel uses of multi-phase clocks, and these generally require two-phase, three-phase, four-phase, and five-phase clocks with evenly distributed phases. Such multiphase clocks can be produced directly by an oscillator. Geerjan Joordens and the present inventor, Wenyi Song, describe a multiphase ring oscillator in United States Patent Application Publication, US 2004/0032300 A1, published Feb. 19, 2004.

Such multiphase ring oscillator places an even-number of cross-coupling transistors and inverters end-to-end in a ring configuration. The output phases are tapped at the output of each inverter. Four such inverters will produce a four-phase output. Odd numbers of inverters cannot be used because the total phase shift around the loop is not 360-degrees.

A way to generate an odd-number of multiphase clocks with equally spaced phases is with a divider. Externally generated and precision reference clock sources can then be used to synthesize multiphase clocks. One example is the divider used to generate three-phase clocks in the Philips Trimedia Processor.

Digital frequency dividers are used in computer and communications circuits to synthesize various utility clocks from a reference oscillator. A digital frequency divider takes a clock signal “cki” as the input, and outputs a new clock signal “cko”. The frequency of cko is the frequency of cki divided by an integer. Such dividers can be implemented in logic as fixed divisor divide-by-n, or programmable divisor divide-by-m.

Synchronous-type dividers and counters clock all the memory elements in parallel with one clock. Programmable digital frequency dividers can be implemented with finite-state-machines (FSM), e.g., with pencil-and-paper, or using logic synthesis tools such as Synopsys Design Compiler. Direct digital synthesis (DDS) is another method, it uses an accumulator clocked by an input cki. During every input clock cycle, the accumulator adds a fixed integer “P” to its content. A number “P” can be selected such that at the end of every “N” input clock cycles, the accumulator overflows. Thus the overflow output functions as the output “cko” of the frequency divider.

Asynchronous-type dividers and counters use a clock to trigger the first flip-flop in a chain, and then the Q-outputs of previous stages are used to clock the next succeeding stages. For example, ripple, decade, and up-down counters employ asynchronous techniques.

Briefly, a multi-phase frequency divider embodiment of the present invention comprises dynamic inverters connected in a ring and the intermediate nodes around the ring are stabilized with cross-coupled latches.

An advantage of the present invention is a multi-phase digital frequency divider is provided.

A further advantage of the present invention is a digital frequency divider is provided that can be implemented with a minimum number of transistors.

A still further advantage of the present invention is that a divider is provided that can be expanded to divide by any even number integer.

The above and still further objects, features, and advantages of the present invention will become apparent upon consideration of the following detailed description of specific embodiments thereof, especially when taken in conjunction with the accompanying drawings.

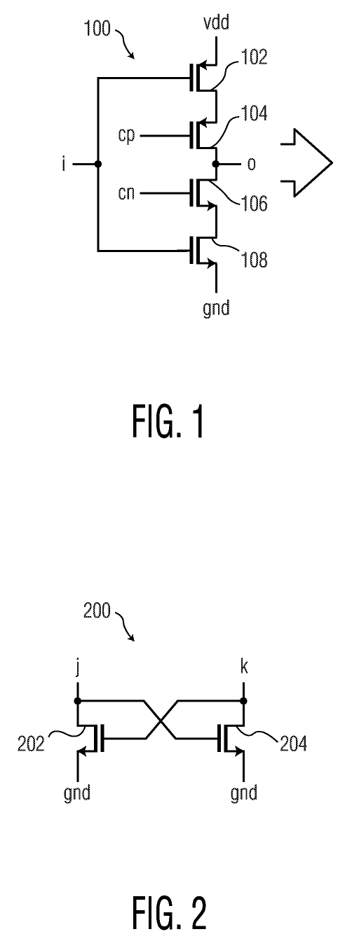

FIG. 1 is a schematic diagram of a dynamic inverter embodiment of the present invention useful as a first building block in a multi-phase frequency divider;

FIG. 2 is a schematic diagram of a nmos cross-latch embodiment of the present invention useful as a second building block in a multi-phase frequency divider;

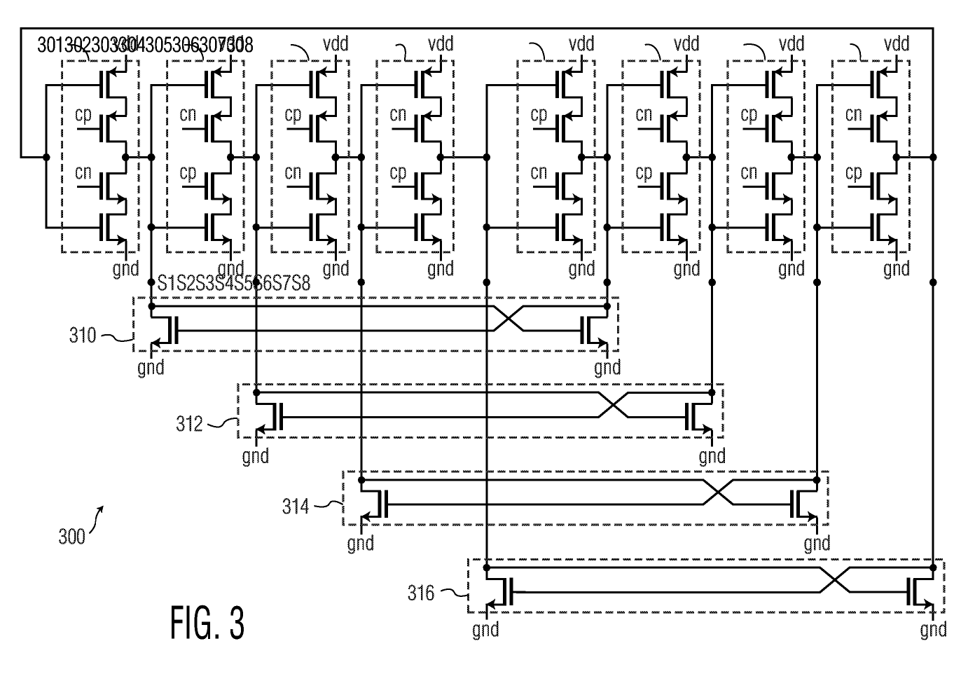

FIG. 3 is a schematic diagram of a multi-phase frequency divider embodiment of the present invention in a representative divide-by-four implementation;

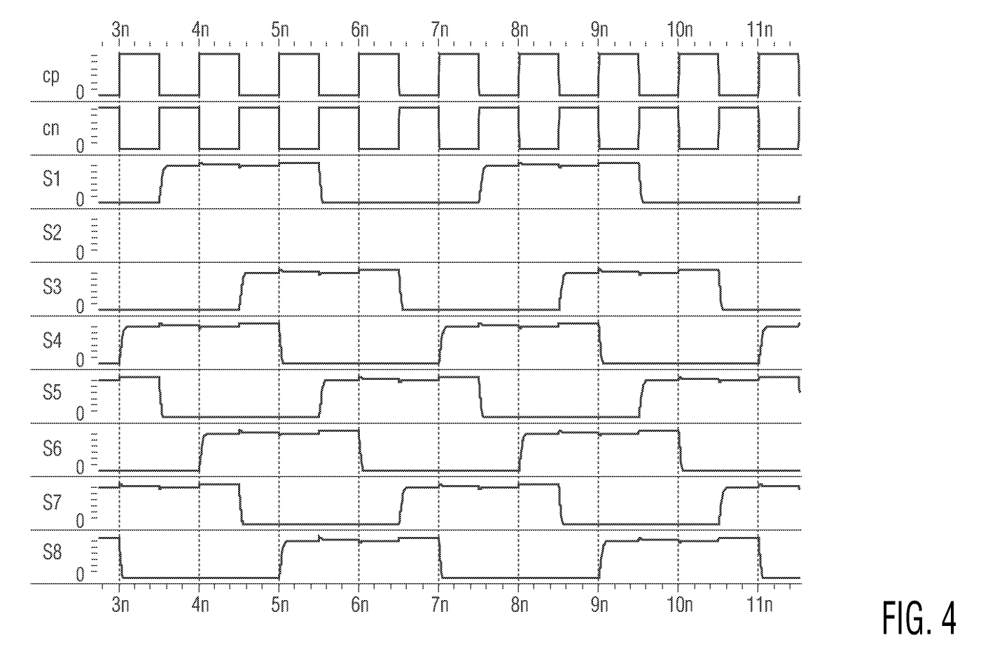

FIG. 4 is a diagram of various key waveforms measured for a prototype implementation of the divider of FIG. 3;

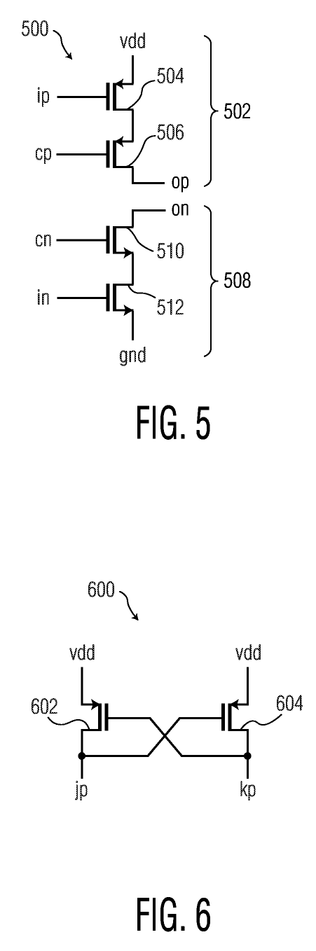

FIG. 5 is a schematic diagram of a dynamic inverter embodiment of the present invention with pmos and nmos parts useful as third and fourth building blocks in a simplified multi-phase frequency divider;

FIG. 6 is a schematic diagram of a pmos cross-latch embodiment of the present invention useful as a fifth building block in a simplified multi-phase frequency divider;

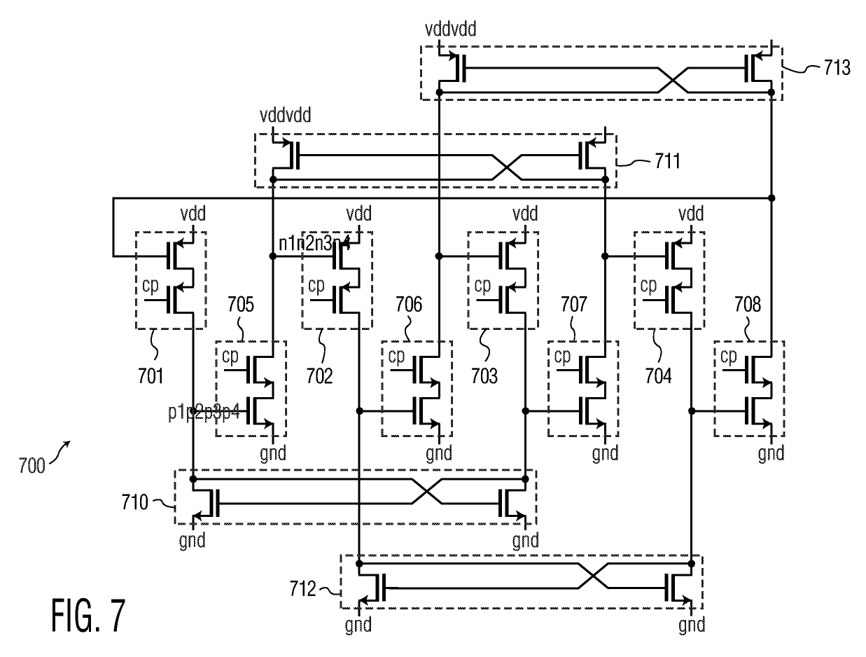

FIG. 7 is a schematic diagram of a simplified multi-phase frequency divider embodiment of the present invention in a representative divide-by-four implementation that improves over that illustrated in FIG. 3;

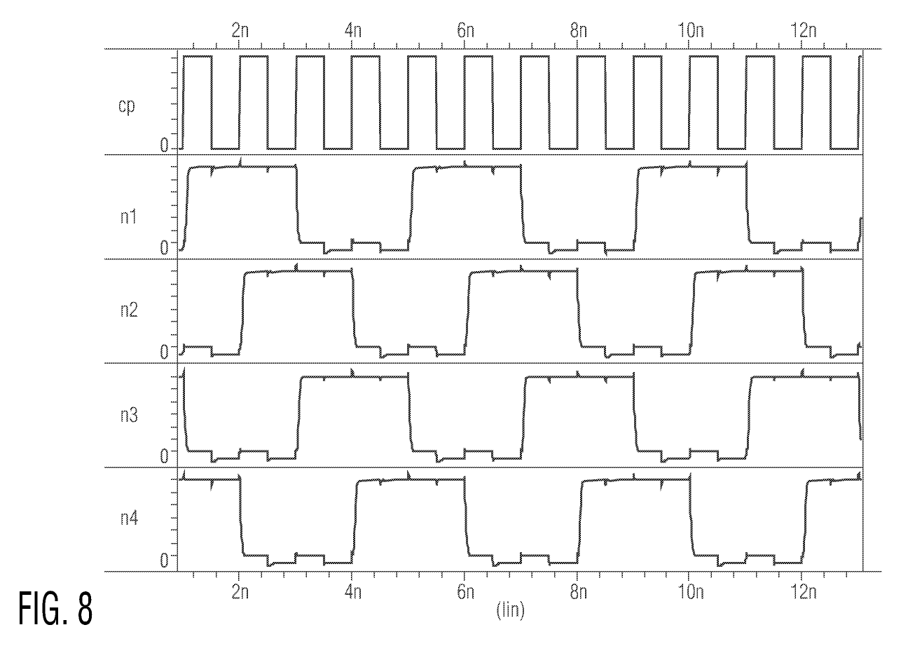

FIG. 8 is a diagram of various key waveforms measured for a prototype implementation of the divider of FIG. 7; and

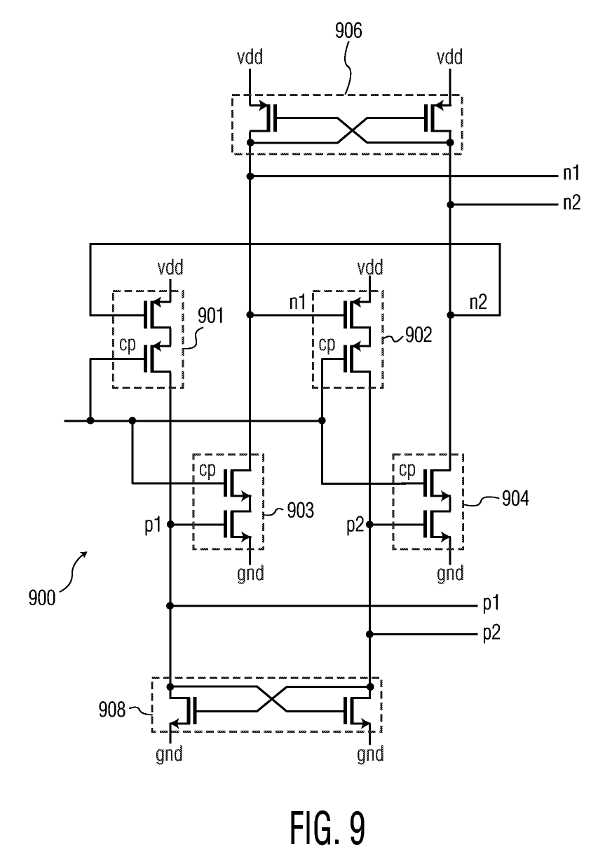

FIG. 9 is a schematic diagram of a divide-by-two multi-phase frequency divider embodiment of the present invention with quadrature outputs and that uses only twelve transistors.

FIG. 1 represents a dynamic inverter embodiment of the present invention, and is referred to herein by the general reference numeral 100. The dynamic inverter 100 is connected between a power rail (vdd) and ground (gnd), and includes an input (i), a clock positive input (cp), a clock negative input (cn), and an output (o). It is constructed with four transistors, two pmos types 102 and 104, and two nmos types 106 and 108. When a clock “cp” is low, and its complement “cn” is high, the output of the inverter is the complement of its input. When “cp” is low and “cn” is high, the output will be in a high impedance state.

FIG. 2 represents a second building block, a cross-latch embodiment of the present invention, and is referred to herein by the general reference numeral 200. The cross-latch 200 comprises cross-connected transistors 202 and 204. The two “j” and “k” nodes will latch complementary values.

FIG. 3 represents a divide-by-four multi-phase frequency divider embodiment of the present invention, and is referred to herein by the general reference numeral 300. It can be constructed with the two building blocks illustrated in FIGS. 1 and 2, e.g., dynamic inverter 100 and cross-latch 200. Inverters 301-308 are connected head-to-tail in a ring. The input clocks “cp” and “cn” are reversed at every other inverter. Four latches 310, 312, 314, and 316 are connected, respectively, to latch the outputs of complementary pairs of inverters 301 and 305; 302 and 306; 303 and 307; and, 304 and 308. These force, or initialize, the proper states around the ring. The multiphase outputs are S1-S4 and their corresponding complements S5-S8.

Divider 300 can be modified by changing the number of inverters in the ring to divide by any even integer “E”. The total number of inverters in the ring will be 2*E, with E-number of cross-connected latches. The multiphase outputs will always be evenly distributed for any divisor E.

FIG. 4 represents the waveforms that were measured in a prototype implementation of the divide-by-four multi-phase frequency divider 400. It can be seen that output S1 is complemented by S5, output S2 is complemented by S6, output S3 is complemented by S7, and output S4 is complemented by S8. There is an even phase shift of 90-degrees amongst the phases.

It is possible to simplify divider 300 and use half the number of inverters and only the “cp” clock input. To do this, slightly different building blocks are used.

FIG. 5 represents a dynamic inverter embodiment of the present invention, and is referred to herein by the general reference numeral 500. The dynamic inverter 500 has a pmos storage half 502 comprising transistors 504 and 506 connected between a power rail (vdd) and a p-output (op). It includes a p-input (ip), a p-clock input (cp). The dynamic inverter 500 further includes an nmos storage half 508 comprising transistors 510 and 512 connected between an n-output (on) and ground (gnd). It further includes an n-input (in), an n-clock input (cn).

FIG. 6 represents a second building block, a pmos cross-latch embodiment of the present invention, and is referred to herein by the general reference numeral 600. The cross-latch 600 comprises cross-connected transistors 602 and 604. The two jp and kp nodes will force a latch of complementary values.

FIG. 7 represents a simplified divide-by-four multi-phase frequency divider embodiment of the present invention, and is referred to herein by the general reference numeral 700. It can be constructed with the building blocks illustrated in FIGS. 2, 5, and 6, e.g., nmos cross-latch 200, pmos storage half 502, nmos storage half 508, and pmos cross-latch 600. The frequency divider 700 uses four dynamic inverters 500 (FIG. 5) split into dynamic pmos storage units 701-704, and dynamic nmos storage units 705-708. The output of each dynamic pmos storage 701-704 is connected to the input of the following dynamic nmos storage units 705-708, forming a ring. The nodes of the pmos storage output are labeled p1-p4, and those of the nmos storage output are labeled n1-n4.

Other even number divisions are possible, for any even integer “E”, each divider requires E-number of dynamic inverters, E-number of nmos cross latches, and E-number of pmos cross latches. The pmos cross latches are con-nected to the output nodes of the nmos storage, and the nmos cross latches are connected to the output nodes of the pmos storage. If node pj is connected to one node of an nmos cross latch, then the other node of the cross latch should be connected to node p(E−j). The same applies to the pmos cross latch connections as well. For any input frequency “F”, the output signals on node n1 to nE run at the same frequency, F/E, with equal phase difference of (F/E)/2 between any two adjacent nodes.

FIG. 8 represents the waveforms that were measured in a prototype implementation of the simplified divide-by-four multi-phase frequency divider 700. It can be seen that outputs n1-n4 have an even phase shift of 90-degrees amongst the four phases.

FIG. 9 represents a divide-by-two, quadrature-phase output, frequency divider embodiment of the present invention, and is referred to herein by the general reference numeral 900. It can be implemented with only twelve transistors. Divider 900 comprises a ring of pmos storage units 901 and 902, and nmos storage units 903 and 904. The divider clock input is applied to the “cp” input of each, and the multi-phase outputs are available as “n1”, “n2”, “p1”, and “p2”. A pmos cross-latch 906 and an nmos cross-latch 908 force the proper bit states around the ring.

Although particular embodiments of the present invention have been described and illustrated, such is not intended to limit the invention. Modifications and changes will no doubt become apparent to those skilled in the art, and it is intended that the invention only be limited by the scope of the appended claims.

What is claimed is:

1. A frequency divider, comprising: a plurality of dynamic inverters connected head-to-tail in a ring configuration; a plurality of cross-latches connected to intermediate nodes between successive ones of the dynamic inverters and providing for the enforcement of complementary bit states at the outputs of opposite dynamic inverters; a divider clock input connected in parallel to every one of the plurality of dynamic inverters; and divider multi-phase output provided in parallel from each output of a dynamic inverter.

2. The frequency divider of claim 1, further comprising: a first building block from which each of the plurality of dynamic inverters are constructed and comprising first and second pmos transistors and first and second nmos transistors connected in a totempole with an output taken at the junction of the second pmos and first nmos transistors, and having an input that is connected to the gate of the first pmos and second nmos transistors, and a positive clock input (cp) that is connected to the gate of the second pmos transistor, and negated clock input (cn) that is connected to the gate of the first nmos transistor.

3. The frequency divider of claim 1, further comprising: a second building block from which each of the plurality of cross-latches are constructed and comprising first and second nmos transistors cross-coupled with the gate of the first connected to the drain of the second, and the gate of the second connected to the drain of the first nmos transistor.

4. The frequency divider of claim 2, further comprising: a divider clock differential input “ckip” connected to a “cp” input of a first one of the plurality of dynamic inverters and a “cn” of a second one of the plurality of dynamic inverters, and alternating thereafter between pairs of stages.

5. The frequency divider of claim 2, further comprising: a divider clock differential input “ckin” connected to a “cn” input of a first one of the plurality of dynamic inverters and a “cp” of a second one of the plurality of dynamic inverters, and alternating thereafter between pairs of stages.

6. The frequency divider of claim 1, further comprising: a third building block pmos storage unit from which odd ones of the plurality of dynamic inverters are constructed and comprising first and second pmos transistors and first and second nmos transistors connected in a totempole with an “op” output, and having an “ip” input connected to the gate of the first pmos transistor, and a positive clock input (cp) connected to the gate of the second pmos transistor; and a fourth building block nmos storage unit from which even ones of the plurality of dynamic inverters are constructed and comprising first and second nmos transistors connected in a totempole with an “on” output, and having an “in” input connected to the gate of the second nmos transistor, and a negated clock input (cn) connected to the gate of the first nmos transistor; a fifth building block from which odd ones of the plurality of cross-latches are constructed and comprising nmos cross-latches connected to the outputs of pairs of the third building block pmos storage units; and a sixth building block from which even ones of the plurality of cross-latches are constructed and comprising pmos cross-latches connected to the outputs of pairs of the third building block nmos storage units.

7. A divide-by-two four-phase frequency divider, comprising: first through fourth inverters connected in a ring, wherein the first and third inverters have first and second pmos transistors connected in series with an inverter output (p1-p2), and the second and fourth inverters have first and second nmos transistors connected in series with an inverter output (n1-n2), and the gates of each first pmos transistor is connected to a corresponding previous inverter output (n1-n2), and the gates of each second nmos transistor is connected to a corresponding previous inverter output (p1-p2), and the gates of all the second pmos and first nmos transistors are connected in parallel to a clock input (cp); an nmos cross-latch connected to hold each of the previous inverter outputs (p1-p2) after each input clock (cp); and a pmos cross-latch connected to hold each of the previous inverter outputs (n1-n2) after each input clock (cp); wherein, a divider multi-phase output provided in parallel from each inverter outputs (p1, p2, n1, n2).

8. A method of generating multi-phase signals, comprising: arranging a plurality of inverters in a ring; clocking all said inverters with a common input clock; and bridging cross-latches across opposite ones of the plurality of inverters to enforce bit initialization and sample holding; wherein, the output of each inverter provides a multi-phase frequency output evenly distributed in phase with its peers.
